(19) United States
(12) Patent Application Publication
(10) Pub. No.: US 2013/0194441 A1
(43) Pub. Date: Aug. 1, 2013

(54) ELECTRONIC DEVICE AND IMAGING APPARATUS

(71) Applicant: Panasonic Corporation, Osaka (JP)

(72) Inventor: SATOSHI HORIE, Hyogo (JP)

(73) Assignee: PANASONIC CORPORATION, Osaka (JP)

(21) Appl. No.: 13/749,801

(22) Filed: Jan. 25, 2013

(30) Foreign Application Priority Data
Jan. 27, 2012 (JP) 2012-015191

(51) Int. Cl. H03L 5/00; G06F 3/00

(52) U.S. Cl. CPC H03L 5/00; G06F 3/005
USPC 348/207.1; 327/142

(57) ABSTRACT

An electronic device includes a first activation signal generator, a second activation signal generator, a third activation signal generator, a first controller including a first input terminal to which the first and second activation signals are input, and a second input terminal to which the first and third activation signals are input, a second controller that is activated by the first controller. The first controller activates the second controller when any activation signal is input. The second controller detects the first and/or second activation signal after completing its activation and executes a specific operation according to the detection result. The length of the first activation signal is set to not less than the time required for the second controller to become able to detect the first activation signal after the first activation signal starts to be output.

### BACKGROUND

1. Technical Field

The present disclosure relates to an electronic device that performs an activation operation triggered by a primary activation trigger or a secondary activation trigger.

2. Related Art

Electronic devices such as digital cameras typically have an activation mode triggered by activation triggers such as a power switch being pressed (referred to herein as a “primary activation trigger”), and another activation mode triggered by other activation triggers (referred to herein as a “secondary activation trigger”). When the electronic device is activated upon input of an interrupt from a secondary activation trigger while the electronic, device is either turned off or sleeping, the power-off state or sleep state is resumed until the next operation is requested after the operation initiated by the activation trigger is completed. A primary activation trigger as used herein is an activation trigger that generates an activation signal when the user performs an operation to start the electronic device from the off state or wake the electronic device up from a sleep state, and is an activation trigger that generates an activation signal when the user intentionally starts the electronic device. A secondary activation trigger is an activation trigger that generates an activation signal independently from user's intention to start the electronic device. Examples of secondary activation triggers include intermittently receiving GPS signals, regularly searching for a WiFi access point, and determining the connected device when charging a USE device.

Conventionally, a configuration that starts an electronic device in response to a plurality of activation triggers is known (see JP01-255909, A). There is also a situation in which the electronic device must determine the type of activation trigger that triggered starting, and perform an operation specific to the activation trigger. To do so, configurations that have a plurality of input terminals for identifying the type of activation trigger that generated the activation signal, connecting 1:1 each of the signals from the plural activation triggers to each terminal to which each signal is input, are also known.

When the signals from plural activation triggers are connected 1:1 to the input terminals, the number of input terminals increases as the number of activation triggers increases, and the configuration becomes increasingly complex.

### SUMMARY

The present disclosure provides an electronic device that can determine the type of activation trigger using a simple configuration with few input terminals.

An electronic device according to the present disclosure includes a first activation signal generator that generates and outputs a first activation signal when a specific event occurs, a second activation signal generator that generates and outputs a second activation signal corresponding to a specific first state, a third activation signal generator that generates and outputs a third activation signal corresponding to a specific second state, a first controller including a first input terminal to which the first and second activation signals are input, and a second input terminal to which the first and third activation signals are input, and a second controller that is activated by the first controller, receives input of the first and third activation signals, and executes an operation corresponding to the input activation signal. The first controller activates the second controller when any of the first to third activation signals is input. After completing the activation, the second controller detects input of the first activation signal and the second activation signal, and executes a specific operation according to the result of detection of the activation signal. The length of the first activation signal is set to greater than or equal to the time required for the second controller to become able to detect the first activation signal after the first activation signal generator starts outputting the first activation signal.

An electronic device according to the present disclosure can determine the type of activation trigger using a simple configuration with few input terminals. Other objects and attainments together with a fuller understanding of the embodiments will become apparent and appreciated by referring to the following description and claims taken in conjunction with the accompanying drawings.

### BRIEF DESCRIPTION OF THE DRAWINGS

FIG. 1 is a block diagram showing the configuration of an electronic device according to a first embodiment;

FIG. 2 describes the length of the interrupt signal;

FIG. 3 is a flow chart describing the operation of an electronic device according to the first embodiment of the invention;

FIG. 4 is a block diagram showing the configuration of an electronic device having a plurality of interrupt input units according to other embodiment; and

FIG. 5 is a block diagram showing the configuration of an imaging apparatus using the configuration of an electronic device according to the first embodiment.

### DETAILED DESCRIPTION OF EMBODIMENTS

Embodiments are described below with reference to the accompanying drawings. Note that excessively detailed description may be omitted. For example, detailed description of content that is already well-known, and redundant description of elements substantially identical to those well known, may be omitted or simplified. This is to avoid unnecessary redundancy in the following description, and to simplify understanding by those skilled in the related art. The accompanying drawings and following description are provided by the inventor(s) to facilitate understanding by those skilled in the related art, and are not intended to limit the scope of the accompanying claims.

### Problem to be Solved by Present Disclosure

To simplify the configuration for discriminating activation triggers in the electronic device described above, a configuration that inputs activation signals from plural different activation triggers to a common input terminal could conceivably be used. A problem with this configuration is that the plural activation triggers cannot include triggers that holds (keeps) the state of the activation signal. This is further described below.

In some electronic devices, the power switch, which is a primary activation trigger, is a slide switch that mechanically holds (keeps) a particular state (position), and the electronic device enters a sleep state when a specific time has passed with the power switch in the ON position. When a signal from the power switch and an interrupt signal from the secondary activation trigger are input to a common input terminal in this electronic device, a processor that determines the activation trigger cannot receive the signal from the secondary activation trigger and the electronic device cannot be started by the secondary activation trigger.

For example, it is assumed that, when the power switch is ON, the signal input to the input terminal of the processor that determines the activation trigger is LOW. It is assumed that a LOW interrupt signal is also input to this input terminal when an interrupt occurs (when a secondary activation trigger occurs). As a result, when the power switch is ON, the signal input to the input terminal is always LOW regardless of whether an interrupt (secondary activation trigger) has occurred. This is not a problem when the power switch is ON and the electronic device is operating because a controller (such as a microprocessor) of the electronic device can detect interrupts and operate accordingly. However, when the electronic device then enters the sleep state, the controller does not operate and therefore cannot detect interrupt signals (secondary activation triggers).

In view of this problem, the present disclosure discloses an electronic device that enables reducing the number of activation signal input terminals even when handling an activation trigger that holds the activation signal state.

### First Embodiment

An electronic device according to a first embodiment has two input terminals for inputting activation signals generated by three different activation triggers to a first controller. Each activation signal is connected to an information processor to determine the corresponding activation trigger, and the information processor can execute processes corresponding to the activation trigger. The configuration and operation of an electronic device according to this first embodiment are described more specifically below.

### 1. Configuration of Electronic Device

The configuration of an electronic device according to the first embodiment is described below.

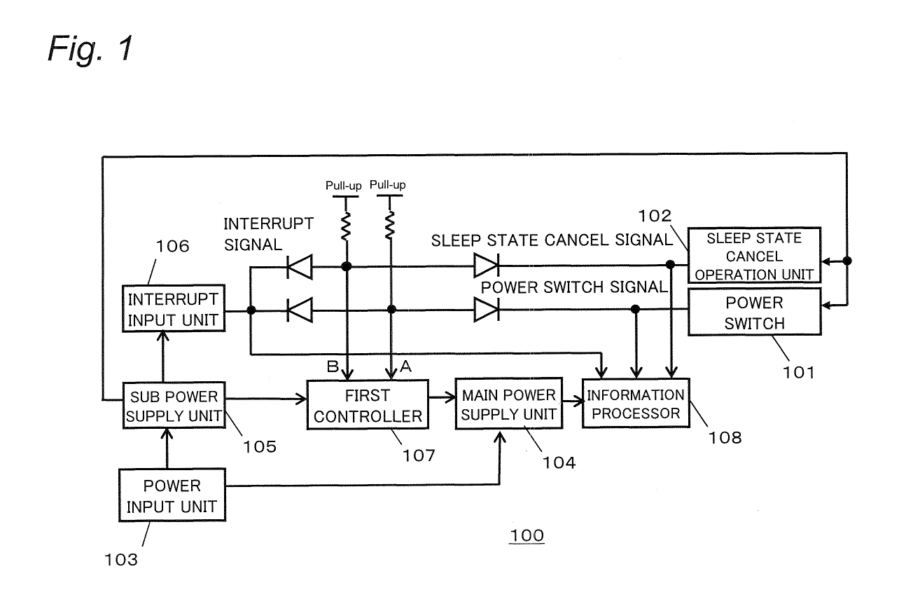

FIG. 1 is a block diagram showing the configuration of the electronic device. This electronic device 100 includes a power switch 101, a sleep state cancel operation unit 102, a power input unit 103, a main power supply unit 104, a sub power supply unit 105, an interrupt input unit 106, a first controller 107, and an information processor 108.

The power switch 101 is a primary activation trigger of the electronic device 100. The power switch 101 switches the main operation of the electronic device 100 on and off. The power switch 101 is a slide switch, and outputs a LOW signal when the switch is ON, and outputs a HIGH signal when the switch is OFF. The LOW signal (activation signal) output when the switch is ON is the “power switch signal.” The power switch 101 is connected to an input terminal A of the first controller 107. The power switch 101 is also connected to the information processor 108.

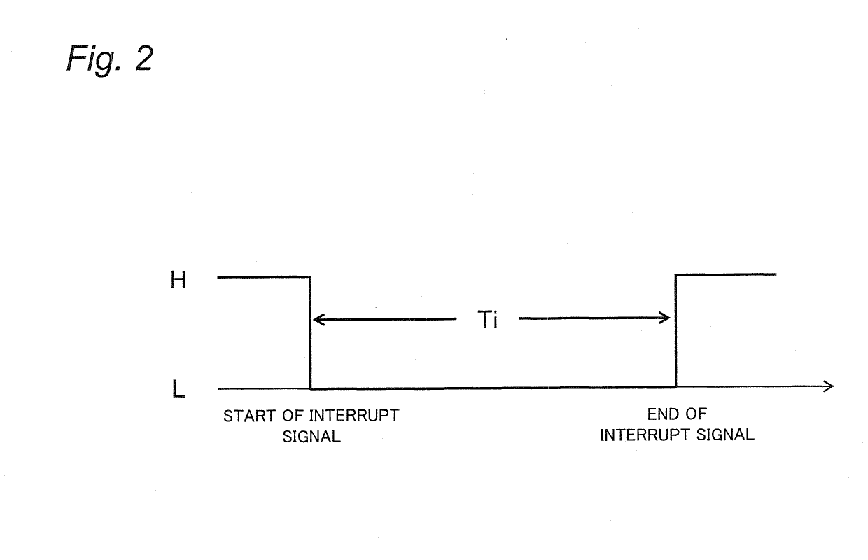

The sleep state cancel operation unit 102 is a primary activation trigger of the electronic device 100. The sleep state cancel operation unit 102 is an operating means that is operated by a user of the electronic device 100 to wake the electronic device 100 from the sleep state. The sleep state cancel operation unit 102 normally outputs a HIGH signal, and outputs a LOW signal when operated by the user. The LOW signal (activation signal) output at this time is the “sleep state cancel signal.” The sleep state cancel signal is a rectangular pulse that goes LOW for a specific time (Ti) as shown in FIG. 2. This specific time (Ti) is set to a period longer than the time required for the information processor 108 to complete the activation process and be enabled to recognize the sleep state cancel signal after the sleep state cancel signal is output (that is, after the sleep state cancel signal is input to the first controller 107). The specific time (Ti) is preferably set to the shortest time in the time range meeting the foregoing condition. The sleep state cancel operation unit 102 could be a button disposed to the electronic device 100, for example, or a touch panel or other operating means. The sleep state cancel operation unit 102 is connected to input terminal B of the first controller 107. The sleep state cancel operation unit 102 is also connected to the information processor 108.

The power input unit 103 is connected to an external power source (not shown in the figure), and supplies power to the main power supply unit 104 and sub power supply unit 105. The power source connected to the power input unit 103 may be an internal battery or an external power source such as an AC supply.

The main power supply unit 104 converts power supplied from the power source connected to the power input unit 103 to a voltage required by the information processor 108 to supply the converted power to the information processor 108. The main power supply unit 104 starts when receiving a signal from the first controller 107, and supplies power to the information processor 108.

The sub power supply unit 105 converts the power supplied from the power source connected to the power input unit 103 to a voltage required by the power switch 101, sleep state cancel operation unit 102, interrupt input unit 106, and first controller 107, and supplies the converted power to them.

The interrupt input unit 106 is a secondary activation trigger. When a specific event occurs, the interrupt input unit 106 generates and outputs an interrupt signal (activation signal) to the first controller 107. The interrupt input unit 106 is, for example, a charge control IC. When a USB cable is connected to the electronic device 100, the charge control IC uses the information processor 108 to make settings for charging the internal battery connected to the power input unit 103.

The interrupt input unit 106 is connected to both input terminal A and input terminal B of the first controller 107. More specifically, one of the two connection nodes between the interrupt input unit 106 and first controller 107 is the connection node (input terminal A) at which the power switch 101 is connected to the first controller 107. The other node is the connection node (input terminal B) at which the sleep state cancel operation unit 102 is connected to the first controller 107. The interrupt input unit 106 is also connected to the information processor 108.

The interrupt input unit 106 outputs a HIGH signal when an interrupt is not asserted, and outputs a rectangular pulse interrupt signal that goes LOW for a specific time (Ti) as shown in FIG. 2 when an interrupt occurs. This specific time (Ti) is set to a period longer than the time required for the information processor 108 to be in a state where it completes the activation process and can recognize the interrupt signal after the interrupt signal is output (that is, after the interrupt signal is input to the first controller 107). The specific time (Ti) is preferably set to the shortest time in the time range meeting the foregoing condition.

The first controller 107 operates on power supplied from the sub power supply unit 105. As described above, the first controller 107 receives three activation signals through the input terminals A and B. Specifically, the first controller 107 receives a power switch signal from the power switch 101, a sleep state cancel signal from the sleep state cancel operation unit 102, and an interrupt signal from the interrupt input unit 106 through the input terminals A and B. More specifically, the first controller 107 receives the interrupt signal and power switch signal through the input terminal A, and receives the interrupt signal and sleep state cancel signal through the input terminal B. Note that the power switch signal and interrupt signal connected to the input terminal A are electrically separated by diodes to prevent interference therebetween (see FIG. 1). The interrupt signal and sleep state cancel signal connected to input terminal B are likewise electrically separated by diodes to prevent interference therebetween.

The first controller 107 detects the falling edge of the activation signals (the edge changing from HIGH to LOW) sent from the power switch 101, sleep state cancel operation unit 102, and interrupt input unit 106, and sends a activation control signal to the main power supply unit 104.

The input terminal B of the first controller 107 does not accept the sleep state cancel signal unless input terminal A is LOW (the power switch 101 is OFF). The electronic device 100 can only go from the operating state to the sleep state, or from the sleep state to the operating state, when the power switch 101 is ON. As a result, the sleep state cancel signal for cancelling the sleep state can be accepted through the input terminal B only when the power switch 101 outputs LOW (power switch signal) to the input terminal A.

The information processor 108 includes a CPU and an internal memory, and executes processes rendering the main functions of the electronic device 100. The information processor 108 operates on power supplied from the main power supply unit 104. The information processor 108 detects the activation signals from the power switch 101, sleep state cancel operation unit 102, and interrupt input unit 106, and determines type of the activation trigger (the source of the activation signal). The information processor 108 executes a specific operation based on the determined activation trigger. The information processor 108 also sets a flag in internal memory, and stores information denoting whether or not the electronic device 100 is in the sleep state.

### 2. Operation

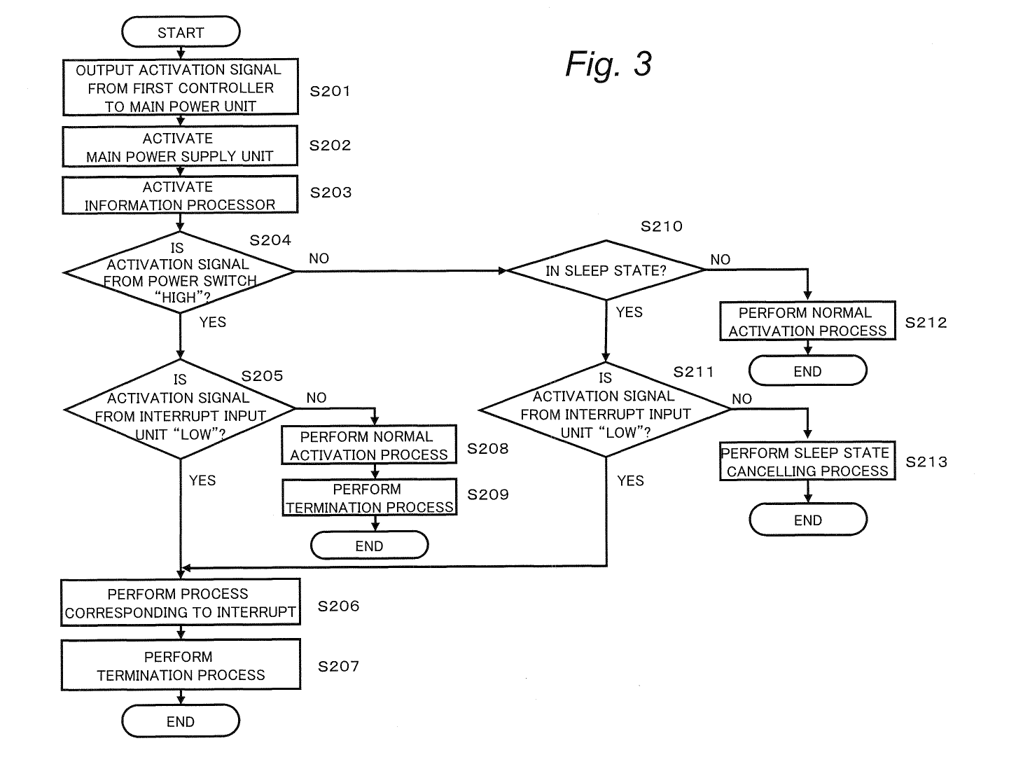

FIG. 3 is a flow chart describing the operation of the electronic device 100 when an activation signal is input to the first controller 107 from the power switch 101, the sleep state cancel operation unit 102, or interrupt input unit 106.

In this embodiment, the electronic device 100 is either turned off (power off state) or in the sleep state, before the activation signal is input to the first controller 107. The power off state is a state in which the power switch 101 is OFF (HIGH) and the main power supply unit 104 is supplying no power. The sleep state is a state which is entered when a specific time has passed since the power is turned ON, for example, and in which the power switch 101 is ON (LOW) and the main power supply unit 104 is supplying no power. In the power off state and the sleep state, the sub power supply unit 105 supplies power to the units described above, and the first controller 107 is waiting for an activation signal to be input.

Referring to FIG. 3, when a activation signal is input from either one of the power switch 101, the sleep state cancel operation unit 102, and the interrupt input unit 106 to the first controller 107 in the power off state or the sleep state, the first controller 107 outputs a signal to start the information processor 108 to the main power supply unit 104 (step S201). When the signal from the first controller 107 is input, the main power supply unit 104 starts (step S202). The main power supply unit 104 then supplies the power required for the information processor 108 to be activated to the information processor 108. After power is supplied from the main power supply unit 104, the information processor 108 performs the internal initialization operation, and then completes an activating operation within a specific time (step S203).

After completing the activation operation, the information processor 108 checks for a signal from the power switch 101 (step S204). When the signal from the power switch 101 is HIGH (the power switch 101 is OFF), that is, when the power switch signal is not output from the power switch 101 and the electronic device 100 is in the power off state (YES in step S204), the information processor 108 checks for a signal from the interrupt input unit 106 (step S205).

When the signal from the interrupt input unit 106 is LOW, that is, when the interrupt signal is output from the interrupt input unit 106 (YES in step S205), the information processor 108 determines that the interrupt input unit 106 is the activation trigger, and executes a process required for the interrupt (step S206). For example, when the interrupt is an interrupt caused by insertion of a USB cable, the information processor 108 controls charging of a battery connected to the power input unit 103 using power from the external power source connected to the power input unit 103 through the USB cable.

After the required process is completed, the information processor 108 executes a termination process (step S207) and returns to the previous state. The previous state is the “power off state” when the termination process (step S207) follows a YES decision in step S204 (the power switch 101 is OFF). When the termination process (step S207) follows a NO decision in step S204 (the power switch 101 is ON), the previous state is the “sleep state”.

When in step S205 the signal from the interrupt input unit 106 is not LOW, that is, when the signal from the interrupt input unit 106 is not an interrupt signal (NO in step S205), the information processor 108 determines that the interrupt input unit 106 is not the activation trigger. More specifically, the information processor 108 determines that the power switch 101 is turned OFF to stop the power switch signal in a period after the power switch 101 is previously turned on to start outputting the activation signal and until input of the power switch signal from the power switch 101 is confirmed in step S204. As a result, the information processor 108 determines that the power switch 101 is the activation trigger, executes the normal activation process (step S208), executes the termination process (step S209), and then resumes the previous state (sleep state).

When the activation signal from the power switch 101 is not HIGH in step S204, that is, when the power switch 101 is ON and the power switch signal can be confirmed, the information processor 108 checks the flag stored in the internal memory and determines whether the electronic device 100 is in the sleep state (step S210). When in the sleep state (YES in step S210), the information processor 108 checks the interrupt signal from the interrupt input unit 106 (step S211).

When in step S211 the activation signal from the interrupt input unit 106 is LOW, that is, when an interrupt signal is received from the interrupt input unit 106 (YES in step S211), the information processor 108 determines that the interrupt input unit 106 is the activation trigger, and goes to step S206.

When not in the sleep state in step S210 (NO in step S210), the information processor 108 determines that the power switch 101 is the activation trigger, and executes the normal activation process (step S212).

When in step S211 the activation signal from the interrupt input unit 106 is not LOW, that is, when the interrupt signal is not received from the interrupt input unit 106 (NO in step S211), the information processor 108 determines that the sleep state cancel operation unit 102 is the activation trigger, and executes a process to cancel the sleep state (step S213).

As described above, three activation signals including a power switch signal, sleep state cancel signal, and interrupt signal, can be input to the two input terminals A and B of the first controller 107 in the electronic device 100 according to this embodiment. When any activation signal is input, the first controller 107 starts the information processor 108. The information processor 108 completes its own activation process, and then determines the type of the activation trigger. The interrupt signal from the interrupt input unit 106, which is one of the activation triggers, is output continuously (that is, remains LOW) for a period that is longer than the time required for the information processor 108 to confirm the activation trigger after the interrupt signal is input to the first controller 107. As a result, the information processor 108 can confirm the activation trigger, and thus the electronic device 100 does not need to have as many activation trigger input terminals as activation triggers (three in this example). Therefore the number of input terminals can be reduced.

### 3. Effect, Etc

The electronic device 100 according to this embodiment has an interrupt input unit 106 that generates and outputs an interrupt signal (first activation signal) when a specific event occurs, a power switch 101 that generates and outputs a power switch signal (second activation signal) according to the state of the power switch 101; a sleep state cancel operation unit 102 that generates and outputs a sleep state cancel signal (third activation signal) when the sleep state is cancelled, a first controller 107 that has a first input terminal A to which the interrupt signal and the power switch signal are input, and a second input terminal B to which the interrupt signal and sleep state cancel signal are input, and an information processor 108 (second controller) that is booted by the first controller 107, receives the interrupt signal, power switch signal, and sleep state cancel signal as inputs, and executes an operation according to the input activation signal. The first controller 107 activates (starts) the information processor 108 when the interrupt signal, power switch signal, or sleep state cancel signal is input. After finishing the activation, the information processor 108 detects input of the interrupt signal and power switch signal, and performs a specific operation based on the detection result. The length Ti of the interrupt signal is set to a period longer than required for the information processor 108 to detect the interrupt signal after the interrupt input unit starts outputting the interrupt signal.

The first controller 107 receives the interrupt signal and power switch signal through the input terminal A, and receives the interrupt signal and sleep state cancel signal through the input terminal B, and therefore the number of activation signal input terminals can be reduced compared with the number of activation signals.

By setting the length Ti of the interrupt signal as described above, the information processor 108 can be enabled to reliably detect the interrupt signal after booting.

### Other Embodiments

The first embodiment is described above as an example of the technology disclosed herein. However, the technology disclosed in this disclosure is not limited thereto, and can also be applied to other embodiments including desirable changes, substitutions, additions, or subtractions. Other embodiments are also possible by combining elements of the first embodiment described above in other ways. Examples of other embodiments are described below.

Three activation triggers including an interrupt signal, power switch signal, and sleep state cancel signal, are described as examples of activation triggers in the foregoing embodiment. The types of activation triggers are, however, not so limited. The concept of the present disclosure can be applied if the number of activation triggers is greater than the number of activation trigger input terminals.

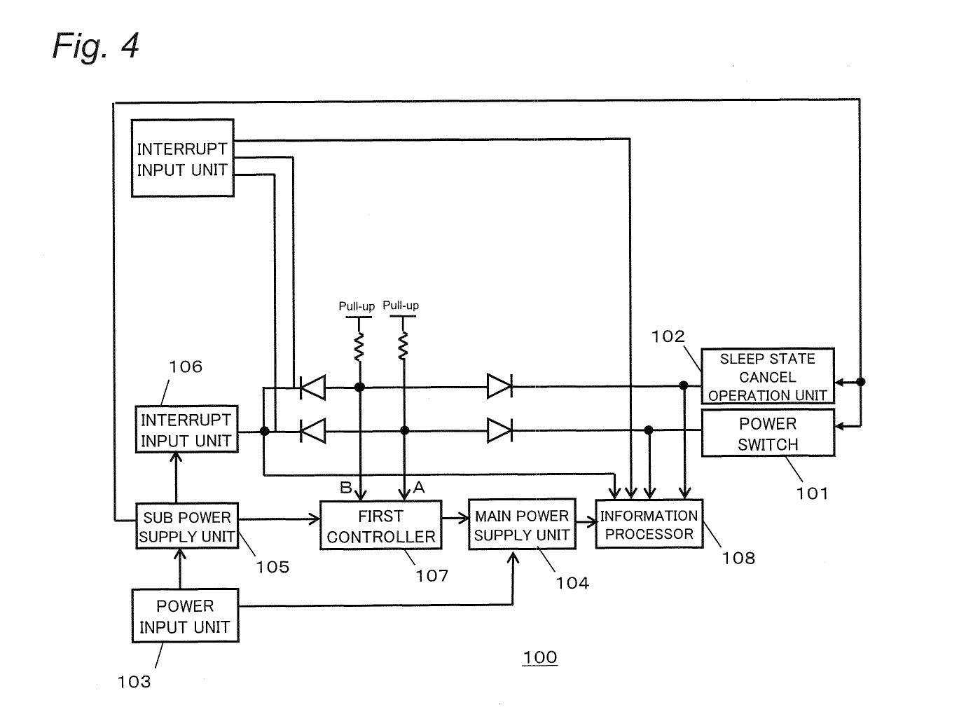

In addition to the charging control IC described above, other examples of the interrupt input unit 106 include GPS modules, WiFi modules, and NFC (near-field communication) modules. A plurality of interrupt input units could also be disposed in the electronic device 100. In this implementation, increasing the number of activation signal input terminals can be prevented by using a configuration such as shown in FIG. 4.

The power switch 101 in the foregoing embodiment is a slide switch, but any configuration that mechanically holds the ON or OFF position can be used. For example, a pushbutton switch that changes the output state between HIGH and LOW each time the conduction state is changed by pressing the button, a toggle switch, or a rotary switch could be used.

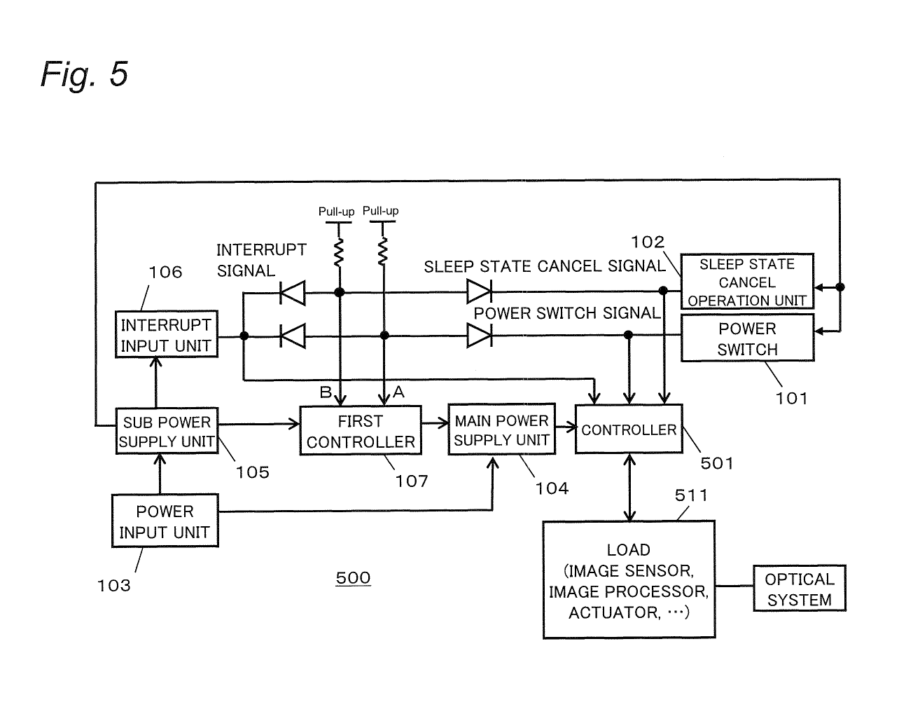

The concept of control related to activation triggers described in the foregoing embodiment can also be applied to a variety of electronic devices. Examples include digital cameras, movie cameras, smartphones, and other imaging apparatus with a function for taking pictures. FIG. 5 shows the configuration of an exemplary imaging apparatus employing the configuration of an electronic device shown in FIG. 1. This imaging apparatus 500 captures a subject image incident to an image sensor through an optical system to generate an image signal, processes the generated image signal with an image processor, and records on a memory card or other recording medium.

The imaging apparatus 500 includes a controller 501 that controls operation of the imaging apparatus 500, and a load 511 that is controlled by the controller 501. The load 511 includes circuits and members including the image sensor, an image processor for processing the image signals generated by the image sensor, and an actuator for driving the optical system. The information processor 108 shown in FIG. 1 corresponds to the controller 501 shown in FIG. 5.

The foregoing embodiments are described as examples of the technology of the present disclosure disclosed herein, and the accompanying drawings and detailed description are provided for this purpose.

The elements described in the accompanying drawings and detailed description therefore include, in addition to elements that are necessary to solve the problem described above, elements that are not necessary to solve the foregoing problem but are useful for describing the technology of the present disclosure. The fact that elements that are not essential are described in the accompanying drawings and detailed description should therefore not be construed to mean that non-essential elements are essential.

The foregoing embodiments are for describing the technology disclosed by the present disclosure, and changes, substitutions, additions, and thus subtractions within the scope of the accompanying claims and the equivalent thereof are possible.

### INDUSTRIAL APPLICABILITY

The present disclosure discloses technology enabling reducing the number of activation trigger input terminals in an electronic device, and can therefore be used in a wide range of devices including digital still cameras, movie cameras, and cell phones.

What is claimed is:

1. An electronic device comprising:
a first activation signal generator operable to generate and output a first activation signal when a predetermined event occurs;
a second activation signal generator operable to generate and output a second activation signal corresponding to a predetermined first state;
a third activation signal generator operable to generate and output a third activation signal corresponding to a predetermined second state;
a first controller including a first input terminal to which the first and second activation signals are input, and a second input terminal to which the first and third activation signals are input; and
a second controller operable to be activated by the first controller, receive input of the first and third activation signals, and execute an operation corresponding to the input activation signal;
wherein the first controller activates the second controller when any of the first, second or third activation signals is input;
after completing the activation, the second controller detects input of the first activation signal and the second activation signal, and executes a predetermined operation according to the result of detection of the activation signal; and
a length of the first activation signal is set to be no less than a time required for the second controller to become able to detect the first activation signal after the first activation signal generator starts outputting the first activation signal.

2. The electronic device according to claim 1, wherein
the first activation signal is a signal denoting that a power switch of the electronic device is set to an ON state;
the second activation signal is an interrupt signal denoting occurrence of a predetermined event; and
the third activation signal is a signal denoting cancellation of a sleep state of the electronic device.

3. The electronic device according to claim 1, wherein the second activation signal generator includes a switch which can be set to at least two states, and outputs the second activation signal according to the set state of the switch.

4. An imaging apparatus that has an optical system and captures a subject input through the optical system to generate image data, comprising:
a first activation signal generator operable to generate and output a first activation signal when a predetermined event occurs;
a second activation signal generator operable to generate and output a second activation signal corresponding to a predetermined first state;
a third activation signal generator that generates and outputs a third activation signal corresponding to a predetermined second state;
a first controller including a first input terminal to which the first and second activation signals are input, and a second input terminal to which the first and third activation signals are input; and
a second controller operable to be activated by the first controller, receive input of the first and third activation signals, and execute an operation corresponding to the input activation signal;
wherein the first controller activates the second controller when any of the first, second or third activation signals is input;
after completing the activation, the second controller detects input of the first activation signal and the second activation signal, and executes a predetermined operation according to the result of activation signal detection; and
a length of the first activation signal is set to be no less than a time required for the second controller to become able to detect the first activation signal after the first activation signal generator starts outputting the first activation signal.

5. The imaging apparatus according to claim 4, wherein:
the first activation signal is a signal denoting that a power switch of the imaging apparatus is set to an ON state;
the second activation signal is an interrupt signal denoting occurrence of a predetermined event; and
the third activation signal is a signal denoting cancellation of a sleep state of the imaging apparatus.

6. The imaging apparatus according to claim 4, wherein the second activation signal generator includes a switch which can be set to at least two states, and outputs the second activation signal according to a state of the switch.
